(19) United States
(12) Patent Application Publication
(10) Pub. No.: US 2019/0069415 A1
(43) Pub. Date: Feb. 28, 2019

(54) Electroless plating catalyst and method of forming copper metal layer on substrate using the same

(71) Applicant: BGT MATERIALS LIMITED, Manchester (GB)

(72) Inventors: Kuo-Hsin CHANG, Chiayi County (TW); Jia-Cing CHEN, Tainan (TW); We-Jei KE, Hsinchu County (TW); Jingyu ZHANG, HWEIAN (CN); Chung-Ping LAI, Hsinchu County (TW)

(21) Appl. No.: 16/122,573

(22) Filed: Sep. 5, 2018

Related U.S. Application Data
(62) Division of application No. 15/688,059, filed on Aug. 28, 2017.

(51) Int. Cl. H05K 3/18; C23C 18/38; C01B 32/198

(52) U.S. Cl. CPC H05K 3/181; C01B 32/198; C23C 18/38

(57) ABSTRACT

An electroless plating catalyst contains: carbon material powders which include oxygen functional groups, wherein the carbon material powders include oxide of any one of graphene, graphite, carbon nanotube, carbon black, and activated carbon with/without oxidization treatment. Oxygen content of the carbon material powders is 5 wt % to 50 wt % of a total weight of carbon powder material. The carbon material powders include a combination, and the combination is any one of nitrogen (N), sulfur (S), boron (B), fluorine (F), and phosphorus (P), wherein a content of the combination is 1 wt % to 20 wt % of the total weight of the carbon powder material.

### CROSS REFERENCE TO RELATED APPLICATIONS

The present application is a divisional application of U.S. patent application Ser. No. 15/688,059, entitled “electroless plating catalyst and method of forming copper metal layer on substrate using the same” fled on 28 Aug. 2017, which is incorporated herein by reference.

### FIELD OF THE INVENTION

The present invention relates to an electroless plating catalyst and a method of electroless plating using the same which form a copper metal layer on a substrate at low cost.

### DESCRIPTION OF THE PRIOR ART

Electroless plating, also known as chemical or auto-catalytic plating, is a non-galvanic plating method that involves several simultaneous reactions in an aqueous solution, which occur without the use of external electrical power. It is mainly different from electroplating by not using external electrical power.

In the manufacture of printed circuit boards, electroless plating is used to form the conductive part of plated through holes. The non-conductive part is treated with palladium catalyst and then made conductive by electroless copper plating.

stable catalysts for electroless metallization is disclosed in EP 2559486A1, the catalysts include nanoparticles of catalytic metal and cellulose or cellulose derivatives. The catalysts are used in electroless metal plating. The catalysts are free of tin. In 2007, a report is disclosed in [Science 318 (2007) 426] regarding a electroless plating adapted for copper or silver, wherein a non-metallic catalyst (such as polydopamine) is employed in the electroless plating.

EP 2712885A1 taught a method for forming a polymerized film on a surface of a non-conductive material and subsequently forming an electroless metal plating film on the surface is described. The method includes the step of contacting the surface of the material with a solution including (A) an amine compound having at least two functional groups, where at least one of the functional groups is an amino group, and (B) an aromatic compound having at least one hydroxyl group on the aromatic ring. However, it takes 4-24 hours in polymerization.

US20160168715A1 discloses that aqueous dispersions of artificially synthesized, mussel-inspired polyopamine nanoparticles were inkjet printed on flexible polyethylene terephthalate (PET) substrates. Narrow line patterns (4 μm in width) of polydopamine resulted due to evaporatively driven transport (coffee ring effect). The printed patterns were metallized via a site-selective Cu electroless plating process at a controlled temperature (30° C.) for varied bath times. The lowest electrical resistivity value of the plated Cu lines was about 6 times greater than the bulk resistivity of Cu. But this method takes 24 hours in polymerization. Furthermore, a PH range of dopamine in polymerization is 6.5 to 9.5, thus reducing self-polymerization rate of dopamine.

The present invention has arisen to mitigate and/or obviate the afore-described disadvantages.

### SUMMARY OF THE INVENTION

The primary objective of the present invention is to provide an electroless plating catalyst and a method of electroless plating using the same which form a copper metal layer on a substrate at low cost.

Another objective of the present invention is to provide an electroless plating catalyst and a method of electroless plating using the same which form a printed circuit or antenna on a substrate.

To obtain above-mentioned objectives, an electroless plating catalyst provided by the present invention contains: carbon material powders which include oxygen functional groups, and the oxygen functional groups at least consists of any one of lactol, ester, hydroxyl, epoxy, and ketone.

The carbon material powders include oxide of any one of graphene, graphite, carbon nanotube, carbon black, and activated carbon.

Preferably, oxygen content of the carbon material powders is 5 wt % to 50 wt % of a total weight of carbon powder material.

Preferably, the carbon material powders include a combination, and the combination is any one of nitrogen (N), sulfur (S), boron (B), fluorine (F), and phosphorus (P), wherein a content of the combination is 1 wt % to 20 wt % of the total weight of the carbon powder material.

In another embodiment, an electroless plating catalyst contains a mixture of carbon material powders which include oxygen functional groups, dispersant, and solvent, the oxygen functional groups at least consist of any one of lactol, ester, hydroxyl, epoxy, and ketone.

Preferably, a content of solid of the mixture is 1 wt % to 60 wt % of a total weight of the mixture, a content of the solvent is 40 wt % to 99 wt % of the total weight of the mixture, and a content of the dispersant is 0.1 wt % to 40 wt % of the total weight of the solid of the mixture.

Preferably, the mixture is graphene oxide.

Preferably, the carbon material powders include oxide of any one of graphite, carbon nanotube, carbon black, and activated carbon, and the mixture further includes adhesive which is made of polymer or resin, wherein a content of the adhesive is 0.1 wt % to 30 wt % of the total weight of the solid of the mixture.

Preferably, the dispersant is ionic dispersant or non-ionic dispersant, and the solvent is any one or a combination of pure water, organic solvent, and inorganic solvent.

Preferably, the mixture of electroless plating catalyst ink further includes thicker, a content of which is 1 wt % to 5 wt % of the solid of the mixture.

In addition, a method of forming a copper metal layer on a substrate contains steps of:
a. preparing electroless plating catalyst ink, wherein the electroless plating catalyst ink comprises a mixture of carbon powder material including the oxygen functional groups, dispersant, and t solvent;
b. printing the electroless plating catalyst ink on a substrate so as to produce a circuit pattern or antenna and drying the electroless plating catalyst ink; and
c. soaking the substrate on which the electroless plating catalyst ink is printed in electroless plating solution so as to form a copper metal layer on the electroless plating catalyst ink.

Preferably, oxygen content of the carbon material powders is 5 wt % to 50 wt % of a total weight of the carbon material powders.

Preferably, the carbon material powders include a combination, and the combination is any one of nitrogen (N), sulfur (S), boron (B), fluorine (F), and phosphorus (P), wherein a content of the combination is 1 wt % to 20 wt % of the total weight of the carbon powder material.

Preferably, the mixture is graphene oxide.

Preferably, the carbon material powders include oxide of any one of graphite, carbon nanotube, carbon black, and activated carbon, and the mixture further includes adhesive which is made of polymer or resin, wherein a content of the adhesive is 0.1 wt % to 30 wt % of the total weight of the solid of the mixture.

Preferably, the dispersant is ionic dispersant or non-ionic dispersant, and the solvent is any one or a combination of pure water, organic solvent, and inorganic solvent.

Preferably, the mixture of electroless plating catalyst ink further includes thicker, a content of which is 1 wt % to 5 wt % of the solid of the mixture.

Preferably, the electroless plating solution formaldehyde-based electroless copper plating solution.

### BRIEF DESCRIPTION OF THE DRAWINGS

FIG. 1 is a flow chart of a method of forming a copper metal layer on a substrate according to a preferred embodiment of the present invention.

FIGS. 2A to 2B are schematic views respectively showing printing electroless plating catalyst ink on a substrate and forming a copper metal layer on the electroless plating catalyst ink according to the preferred embodiment of the present invention.

FIG. 3 is a schematic view showing the application of the electroless plating catalyst and a method of forming the copper metal layer on the substrate using the same according to the preferred embodiment of the present invention.

FIG. 4 is a schematic view showing another application of the electroless plating catalyst and the method of forming the copper metal layer on the substrate using the same according to the preferred embodiment of the present invention.

### DETAILED DESCRIPTION OF THE PREFERRED EMBODIMENTS

An electroless plating catalyst according to a preferred embodiment of the present invention is applied to electroless plating and comprises carbon material powders which include oxygen functional groups, and the oxygen functional groups at least consists of any one of lactol, ester, hydroxyl, epoxy, and ketone, wherein the carbon material powders include oxide of any one of graphene, graphite, natural graphite, carbon nanotube, carbon black, and activated carbon.

The carbon material powders are oxidized to produce various oxygen functional groups, chemical formulas of which are represented as follows:

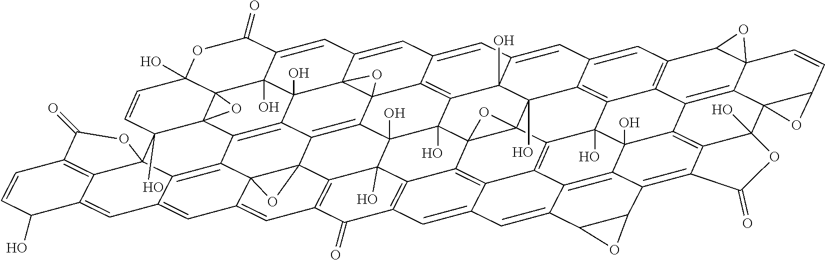

### Cited: Nature Chemistry 1 (2009) 403.

It is to be noted that oxygen content of the activated carbon is 1 wt % to 13 wt %, oxygen content of the natural graphite is 0.5 wt %, oxygen content of oxide of the graphene is 40 wt %, and oxygen content of manufacture material of the oxide of the graphene is 0.5 wt % to 20 wt %. Preferably, oxygen content of the carbon material powders including the oxygen functional groups is 5 wt % to 50 wt % of a total weight of carbon powder material.

To test an application of the carbon material powders to electroless plating, the carbon material powders are put into electroless plating solution (i.e. formaldehyde-based electroless copper plating solution), and the electroless plating is executed for 30 minutes at 50° C. so as to observe whether copper deposition produces, wherein a test result is listed in Table 1.

TABLE 1

| | | Producing copper |
|---|---|---|
| Sample No. | Carbon powder material | deposition |
| 1 | conductive carbon black | No |
| 2 | natural graphite | No |
| 3 | high quality graphene | No |
| 4 | activated carbon | Yes |
| 5 | oxidized natural graphite | Yes |
| 6 | oxidized conductive carbon black | Yes |
| 7 | graphene oxide | Yes |

Thereby, the oxygen functional groups of the carbon material powders are used as a catalyst of electroless plating copper.

Preferably, the carbon material powders include a combination, and the combination is any one of nitrogen (N), sulfur (S), boron (B), fluorine (F), and phosphorus (P), wherein a content of the combination is 1 wt % to 20 wt % of the total weight of the carbon powder material.

An electroless plating catalyst ink according to a preferred embodiment of the present invention comprises: a mixture of the carbon powder material including the oxygen functional groups, dispersant, and solvent, wherein the oxygen functional groups at least consists of any one of lactol, ester, hydroxyl, epoxy, and ketone. A content of solid of the mixture is 1 wt % to 60 wt % of the total weight of the mixture, a content of the solvent is 40 wt % to 99 wt % of the total weight of the mixture, and a content of the dispersant is 0.1 wt % to 40 wt % of a total weight of a solid of the mixture.

The mixture of electroless plating catalyst ink includes thicker, a content of which is 1 wt % to 5 wt % of the solid of the mixture.

In one embodiment, the carbon material powders of the mixture of the electroless plating catalyst ink are graphene oxide.

The dispersant is ionic dispersant or non-ionic dispersant. The solvent is any one or a combination of pure water, organic solvent, and inorganic solvent. In other words, the solvent contains one or more carriers, and the one or more carriers are any one of pure water, organic solvent, and inorganic solvent, wherein the non-ionic dispersant contains any one or at least one of P-123, Tween 20, Xanthan gum, Carboxymethyl Cellulose (CMC), Triton X-100, Polyvinylpyrrolidone (PVP), and Brji 30; wherein the non-ionic dispersant consists of any one or a combination of at least one of poly(sodium 4-styrenesulfonate) (PSS), 3-[(3-Cholamidopropyl)dimethyl ammonio]-1-propanesufonate (CHAPS), Hexadecyltrimethylammonium bromide (HTAB), Sodium taurodeoxycholate hydrate (SDS), and 1-Pyrenebutyric acid (PBA). The organic solvent consists of any one of N-Methyl-2-pyrrolidone (NMP), IPA (Isopropyl alcohol), ethanol, glycerol, ethylene glycol, butanol, propanol, Propylene glycol monomethyl ether (PGME), and Propylene glycol monomethyl ether acetate (PGMEA).

In another embodiment, the carbon material powders include oxide of any one of graphite, carbon nanotube, carbon black, and activated carbon. The mixture of the electroless plating catalyst ink further includes adhesive which is made of polymer or resin, wherein a content of the adhesive is 0.1 wt % to 30 wt % of the total weight of the solid of the mixture. As using graphene flake or graphene oxide as a filler of the catalyst, any polymer or resin adhesive is eliminated from the mixture of the electroless plating catalyst ink.

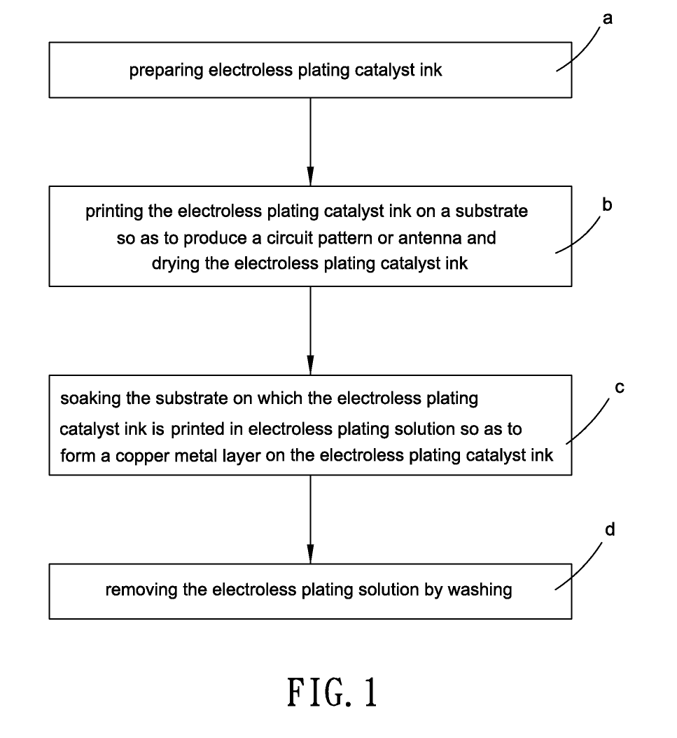

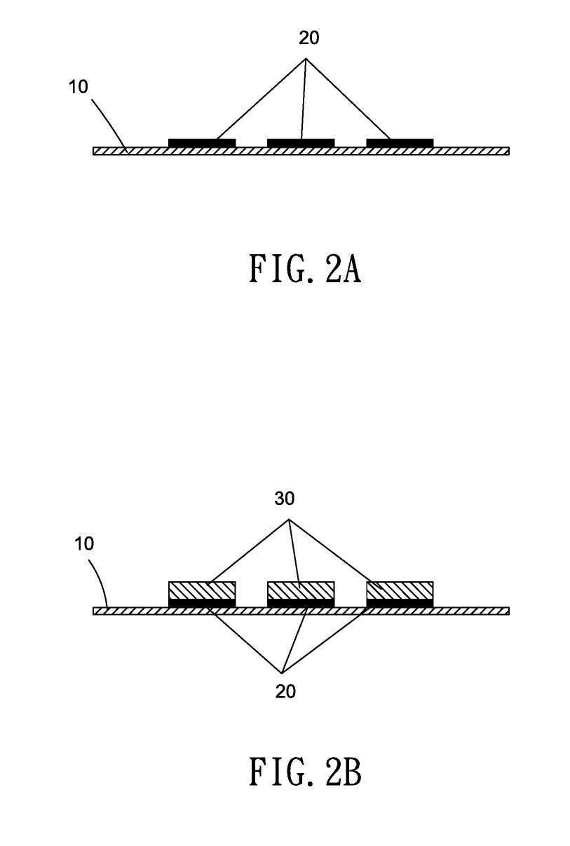

With reference to FIG. 1, a method of forming a copper metal layer on a substrate using the electroless plating catalyst according to a preferred embodiment of the present invention comprises steps of:
a. preparing the electroless plating catalyst ink 20, wherein the electroless plating catalyst ink 20 comprises the mixture of the carbon powder material including the oxygen functional groups, the dispersant, and the solvent;
b. printing the electroless plating catalyst ink 20 on a substrate 10 so as to produce a circuit pattern (as shown in FIG. 2A) and drying the electroless plating catalyst ink 20; and
c. soaking the substrate 10 on which the electroless plating catalyst ink 20 is printed in the electroless plating solution so as to form a copper metal layer 30 on the electroless plating catalyst ink 20 (as illustrated in FIG. 2B).

The substrate 10 is nonmetallic material, such as any one of a printed circuit board (PCB), a plastic plate, a fiberplate, and paper.

The method of the present invention further comprises a step d. removing the electroless plating solution by washing after the step c.

In the step a, the electroless plating catalyst ink 20 comprises the mixture of the carbon powder material including the oxygen functional groups, the dispersant, and the solvent, wherein the oxygen functional groups at least consists of any one of lactol, ester, hydroxyl, epoxy, and ketone. The content of the solid of the mixture is 1 wt % to 60 wt % of the total weight of the mixture, the content of the solvent is 40 wt % to 99 wt % of the total weight of the mixture, and the content of the dispersant is 0.1 wt % to 40 wt % of the total weight of the solid of the mixture, hence the mixture of the electroless plating catalyst ink 20 is coated on the substrate 10 in a printing manner to as to form the circuit pattern or antenna.

In one embodiment, the mixture of the electroless plating catalyst ink 20 is the graphene flake or the graphene oxide which is used as the oxygen functional groups of the carbon material powders so as to print the electroless plating catalyst ink 20 on the substrate 10, and the electroless plating catalyst ink 20 is dried, thereafter the substrate 20, on which the electroless plating catalyst ink 20 is printed, is soaked in the electroless plating solution (i.e. formaldehyde-based electroless copper plating solution) so as to execute electroless plating for 30 minutes at 50° C., thus forming the copper metal layer 30 on the electroless plating catalyst ink 20.

In another embodiment, the mixture of the electroless plating catalyst ink 20 is oxide of any one of graphene, graphite, natural graphite, carbon nanotube, carbon black, and activated carbon so as to use as the oxygen functional groups of the carbon material powders, and the plating catalyst ink 20 further includes the adhesive.

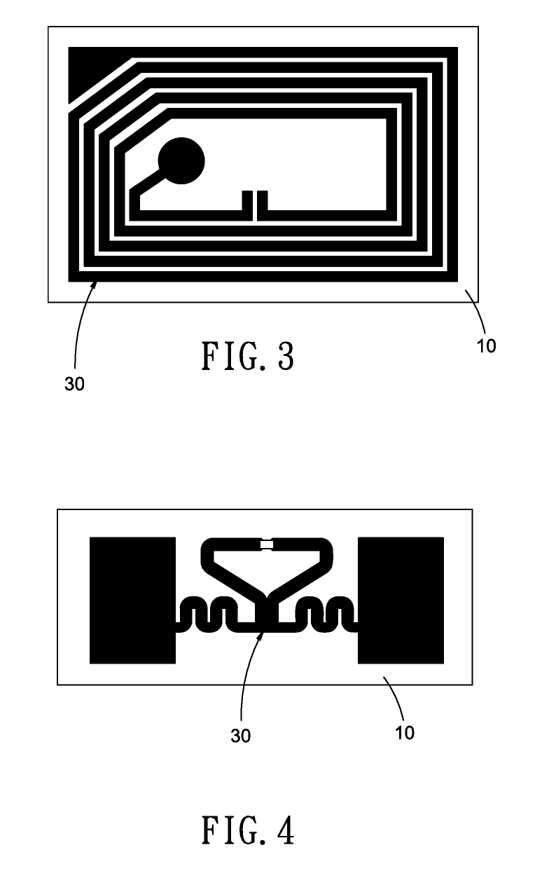

As shown in FIG. 3, the method of the present invention is applied to a printed circuit, wherein the electroless plating catalyst ink 20 consists of: 88 wt % of water, 5 wt % of graphene, 5 wt % of graphene oxide, 1 wt % of non-ionic dispersant, and 1 wt % of polymer resin, and wherein the substrate 10 is polyimide (PI) film.

Thereby, the plating catalyst ink 20 is printed on the PI film and is dried in a baker at 100° C.

Thereafter, the PI film is soaked in formaldehyde-based electroless copper plating solution for 30 minutes at 50° C.

After the copper metal layer 30 deposits, the PI film is washed by water and is dried in the baker.

As illustrated in FIG. 4, the method of the present invention is applied to radio frequency identification (RFID) antenna, wherein the electroless plating catalyst ink 20 consists of: 65 wt % of isopropyl alcohol, 17 wt % of partly oxidized graphite, 1 wt % of non-ionic dispersant, 15 wt % of polymer resin, and 2 wt % of thicker, and wherein the substrate 10 is paper.

Thereby, the electroless plating catalyst ink 20 is printed on the paper and is dried in the baker at 100° C.

Thereafter, the paper is soaked in formaldehyde-based electroless copper plating solution for 20 minutes at 50° C.

After the copper metal layer 30 deposits, the paper is washed by water and is dried in the baker.

It is to be noted that a reading range of the RFID antenna is 10 m after a test.

While the preferred embodiments of the invention have been set forth for the purpose of disclosure, modifications of the disclosed embodiments of the invention as well as other embodiments thereof may occur to those skilled in the art. Accordingly, the appended claims are intended to cover all embodiments which do not depart from the spirit and scope of the invention.

What is claimed is:

1. An electroless plating catalyst comprising: carbon material powders which include oxygen functional groups;
wherein the carbon material powders include any one of graphene, graphite, carbon nanotube, carbon black, and activated carbon with/without oxidization treatment.

2. The electroless plating catalyst as claimed in claim 1, wherein oxygen content of the carbon material powders is 5 wt % to 50 wt % of a total weight of carbon powder material.

3. The electroless plating catalyst as claimed in claim 1, wherein the carbon material powders include a combination, and the combination is any one of nitrogen (N), sulfur (S), boron (B), fluorine (F), and phosphorus (P), wherein a content of the combination is 1 wt % to 20 wt % of the total weight of the carbon powder material.

4. An electroless plating catalyst comprising a mixture of carbon material powders which include oxygen functional groups, dispersant, and solvent;
wherein a content of solid of the mixture is 1 wt % to 60 wt % of a total weight of the mixture, a content of the solvent is 40 wt % to 99 wt % of the total weight of the mixture, and a content of the dispersant is 0.1 wt % to 40 wt % of the total weight of the solid of the mixture.

5. The electroless plating catalyst as claimed in claim 4, wherein the mixture is graphene oxide.

6. The electroless plating catalyst as claimed in claim 4, wherein the carbon material powders include any one of graphite, carbon nanotube, carbon black, and activated carbon with/without oxidization treatment, and the mixture further includes adhesive which is made of polymer or resin, wherein a content of the adhesive is 0.1 wt % to 30 wt % of the total weight of the solid of the mixture.

7. The electroless plating catalyst as claimed in claim 5, wherein the dispersant is ionic dispersant or non-ionic dispersant, and the solvent is any one or a combination of pure water, organic solvent, and inorganic solvent.

8. The electroless plating catalyst as claimed in claim 6, wherein the dispersant is ionic dispersant or non-ionic dispersant, and the solvent is any one or a combination of pure water, organic solvent, and inorganic solvent.

9. The electroless plating catalyst as claimed in claim 7, wherein the mixture of electroless plating catalyst ink further includes thicker, a content of which is 1 wt % to 5 wt % of the solid of the mixture.

10. The electroless plating catalyst as claimed in claim 8, wherein the mixture of electroless plating catalyst ink further includes thicker, a content of which is 1 wt % to 5 wt % of the solid of the mixture.
